(19) United States
(12) Patent Application Publication
(10) Pub. No.: US 2013/0163253 A1
(43) Pub. Date: Jun. 27, 2013

(54) WHITE REFLECTIVE FLEXIBLE PRINTED CIRCUIT BOARD

(71) Applicants: Hirohisa Saito, Osaka-shi (JP); Hideki Matsubara, Osaka-shi (JP); Yoshihiro Akahane, Osaka-shi (JP); Satoshi Yamasaki, Osaka-shi (JP); Makoto Nakabayashi, Osaka-shi (JP)

(72) Inventors: Hirohisa Saito, Osaka-shi (JP); Hideki Matsubara, Osaka-shi (JP); Yoshihiro Akahane, Osaka-shi (JP); Satoshi Yamasaki, Osaka-shi (JP); Makoto Nakabayashi, Osaka-shi (JP)

(73) Assignee: SUMITOMO ELECTRIC INDUSTRIES, LTD., Osaka-shi, Osaka (JP)

(21) Appl. No.: 13/822,159

(22) PCT Filed: Sep. 27, 2011
(86) PCT No.: PCT/JP2011/071991

§ 371 Date: Mar. 11, 2013

(30) Foreign Application Priority Data
Oct. 8, 2010 (JP) 2010-228267

(51) Int. Cl. H05K 1/02; F21V 7/16

(52) U.S. Cl. CPC H05K 1/0277; F21V 7/16
USPC 362/278; 174/254

(57) ABSTRACT

Provided is a flexible printed circuit board having excellent flexibility and a diffusely reflective white surface (white surface) which does not tend to undergo color change even when irradiated with light such as short-wavelength light, i.e., has high light deterioration resistance, and does not tend to undergo color change even when placed in a high-temperature environment, i.e., has excellent thermal deterioration resistance. The white reflective flexible printed circuit board includes a flexible printed circuit board and a surface constituted by a white reflective material layer. The white reflective material layer is composed of a resin composition containing a fluororesin and an inorganic white pigment. Lighting equipment includes the white reflective flexible printed circuit board and an LED mounted on the surface side constituted by the white reflective material layer of the white reflective flexible printed circuit board.

### TECHNICAL FIELD

The present invention relates to a white reflective flexible printed circuit board having a surface functioning as a white reflective surface. More specifically, the present invention relates to a white reflective flexible printed circuit board having a white reflective surface, the flexible printed circuit board being used in, for example, lighting equipment on which a light-emitting diode (LED) is mounted.

### BACKGROUND ART

Recently, with the improvement of the efficiency of LEDs, the range of use of LEDs has also been expanded to lighting equipment used as an alternative light source of an incandescent light bulb, a halogen light bulb, or the like, flat-panel displays, head lamps, and the like. For example, in PTL 1 (Japanese Unexamined Patent Application Publication No. 2002-184209), lighting equipment including a light-emitting portion including a flexible board (flexible printed circuit board) and a plurality of LEDs mounted on a surface of the flexible is proposed (Claim 1).

In the case where an LED is used in lighting, in addition to the realization of high efficiency of the element, the realization of high reflectivity in the lighting is also desired in order to effectively utilize light. PTL 1 discloses lighting equipment in which a surface of the flexible printed circuit board on which the LEDs are mounted is a reflective surface (Claim 2), thus realizing high reflectivity. In such a flexible printed circuit board, it is desirable that the surface functioning as the reflective surface be composed of a material having a high reflectivity (high-reflectivity material) for the purpose of realizing high reflectivity.

In the case where an LED is used in lighting, a head lamp, or the like, since the LED is used in a place where the LED is directly visually observed, it is not desirable that stray light, which is not considered in the design, be reflected only at a specific angle. Therefore, the reflective surface is preferably a diffusely reflective white surface. Thus, a high-reflectivity material having a white color is desired as a material that forms the reflective surface of a flexible printed circuit board.

Regarding a circuit board such as a flexible printed circuit board, the color of the surface of the circuit board often depends on a coating or a film called soldermask or coverlay. The soldermask is usually composed of an epoxy resin-based photosensitizer and can be made white by mixing a pigment such as titanium dioxide. On the other hand, the coverlay is usually composed of a polyimide, and the polyimide material is brownish yellow. Therefore, in such a case, a resin composition prepared by mixing a white pigment with another resin such as an epoxy resin is applied onto a surface of the polyimide so as to form a white surface.

### CITATION LIST

### Patent Literature

### PTL 1: Japanese Unexamined Patent Application Publication No. 2002-184209

### SUMMARY OF INVENTION

### Technical Problem

A white surface formed by a material prepared by mixing a pigment such as titanium dioxide with an epoxy resin-based photosensitizer and a white surface formed by stacking, on a surface of a polyimide, a resin composition prepared by mixing a white pigment with an epoxy resin or the like each have satisfactory initial whiteness and initial reflectivity. However, resin materials including an epoxy resin usually have a large number of carbon-carbon double bonds therein. Thus, when these resin materials absorb short-wavelength light such as ultraviolet, the bonds are cleaved and the color of the resin materials tends to be changed to yellow or brown.

Light emitted from an LED often includes short-wavelength light. In particular, regarding a white LED, white light is obtained by mixing light emitted from a blue LED with yellow light emitted by a phosphor. Therefore, light emitted from the white LED includes short-wavelength light such as ultraviolet. Consequently, the color of the above-described white surfaces are changed to yellow, brown, or the like by the short-wavelength light emitted from the white LED, resulting in a problem of a decrease in the whiteness and a decrease in the reflectivity.

For lighting equipment, flat-panel displays, head lamps, and the like on which an LED is mounted, a high light intensity is required and thus a large amount of electric power is required. Consequently, the amount of heat generated from the element is also large, and thus such lighting equipment, flat-panel displays, head lamps, and the like are often used in an environment at a high temperature, for example, 60° C. or higher. Accordingly, a white surface functioning as a reflective surface of a flexible printed circuit board requires a property that the whiteness or the reflectivity does not tend to decrease even when the flexible printed circuit board is placed in a high-temperature environment for a long time, that is, excellent thermal deterioration resistance. However, white surfaces of existing flexible printed circuit boards do not have such excellent thermal deterioration resistance that sufficiently satisfies the recent requirement.

Furthermore, the reflective surface of lighting equipment, a head lamp, and the like usually has a curved shape or a step-like shape. Therefore, in the case where a flexible printed circuit board functioning as a reflective surface is bonded to the surface of such devices, the shape of the flexible printed circuit board is usually changed so as to conform to the curved shape or the step-like shape. In such a case, when the flexible printed circuit board has low flexibility (high stiffness), a large repulsive force is generated by the change in shape to the curved shape or the step-like shape, resulting in problems in terms of production and performance of the lighting equipment and the like. Therefore, excellent flexibility (low stiffness) is desired for a flexible printed circuit board. However, when the existing method of forming a white surface by using a material of an epoxy resin or the like is employed, with an increase in the thickness of the flexible printed circuit board, there may be problems in that flexibility of the circuit board decreases and cracks are generated when the circuit board is flexed.

As described above, in existing flexible printed circuit boards, a white surface functioning as a reflective surface of lighting equipment does not have a satisfactory light deterioration resistance and thermal deterioration resistance, and improvement in the light deterioration resistance and thermal deterioration resistance has been desired. Furthermore, a white reflective flexible printed circuit board which has excellent reflectivity and whiteness so as to be suitably used as a reflective surface of a flexible printed circuit board for lighting equipment, which is excellent in terms of light deterioration resistance and thermal deterioration resistance, and which has excellent flexibility has been desired.

An object of the present invention is to provide a flexible printed circuit board having excellent flexibility and a diffusely reflective white surface (white surface) which does not tend to undergo color change even when irradiated with light such as short-wavelength light, i.e., has high light deterioration resistance, and does not tend to undergo color change even when placed in a high-temperature environment, i.e., has excellent thermal deterioration resistance.

### Solution to Problem

As a result of intensive studies conducted in order to achieve the above object, the inventors of the present invention found that a flexible printed circuit board having excellent flexibility and a white reflective surface that has both high thermal deterioration resistance and excellent light deterioration resistance can be obtained by forming a surface reflective material composed of a fluororesin containing a white pigment, and completed the present invention. Specifically, the above object is achieved by the structures below.

An invention of Claim 1 is a white reflective flexible printed circuit board including a flexible printed circuit board and a surface constituted by a white reflective material layer, in which the white reflective material layer is composed of a resin composition containing a fluororesin and an inorganic white pigment.

The white reflective material layer in the invention of Claim 1 contains an inorganic white pigment. Thus, the white reflective material layer has excellent whiteness and reflectivity, and the whiteness and reflectivity do not tend to decrease with time even when the white reflective material layer is irradiated with short-wavelength light such as ultraviolet or placed in a high-temperature environment. Specifically, the white reflective flexible printed circuit board according to claim 1 has excellent light deterioration resistance and thermal deterioration resistance. It is believed that this is because the fluororesin constituting the white reflective material layer has a small content of carbon-carbon double bond, and thus the cleavage of a bond by heat or light does not frequently occur, and color change does not tend to occur.

In addition, the white reflective material layer is composed of a fluororesin having a low stiffness (Young's modulus), and thus a repulsive force generated as a result of a change in shape, such as bending, is small (that is, the resilience is small). Consequently, the white reflective material layer does not impair flexibility of the flexible printed circuit board. Thus, in the application to lighting or the like, even when a white reflective flexible printed circuit board is bonded so as to conform to a curved shape or a step-like shape, the flexible printed circuit board and the white reflective material layer are not repelled from each other and the resulting printed circuit board can have excellent flexibility.

Examples of the flexible printed circuit board in the invention of Claim 1 include known flexible printed circuit boards used in, for example, lighting equipment including an LED. The white reflective material layer is formed so as to cover a surface of the flexible printed circuit board. When lighting equipment including an LED is prepared, the LED is mounted on the surface of the flexible printed circuit board. In the case where a surface of the flexible printed circuit board is covered with a coverlay, the white reflective material layer is formed on the coverlay.

An invention of Claim 2 is the white reflective flexible printed circuit board according to Claim 1, in which the fluororesin is selected from the group consisting of an ethylene-tetrafluoroethylene copolymer, a tetrafluoroethylene-hexafluoropropylene copolymer, a tetrafluoroethylene-perfluoro alkyl vinyl ether copolymer, and polytetrafluoroethylene.

The term “fluororesin” refers to a resin containing fluorine and having a C—F bond. Specific examples of the fluororesin include ethylene-tetrafluoroethylene copolymers (ETFE), tetrafluoroethylene-hexafluoropropylene copolymers (FEP), tetrafluoroethylene-perfluoro alkyl vinyl ether copolymers (PFA), and polytetrafluoroethylene (PTFE). A fluororesin selected from these fluororesins may be used alone. Alternatively, these may be used as a mixture of two or more fluororesins.

Solder reflow, which is excellent in terms of productivity, is often used as a method for mounting an element such as an LED or an electronic device on a flexible printed circuit board. The maximum temperature of solder reflow is usually about 260° C. Accordingly, fluororesins having a high melting point, the fluororesins being capable of withstanding the maximum temperature of solder reflow, for example, FEP having a melting point of 270° C., PFA having a melting point of 305° C., and PTFE having a melting point of 327° C. can be preferably used as the fluororesins in view of a reflow-resistance property (property of capable of withstanding the maximum temperature of reflow). However, as described below, even a fluororesin having a low melting point may be preferably used by being cross-linked so as to improve heat resistance.

An invention of Claim 3 is the white reflective flexible printed circuit board according to Claim 1 or 2, in which the fluororesin has a carbon-hydrogen bond and is cross-linked by irradiation with ionizing radiation.

Fluororesins having a carbon-hydrogen bond can be cross-linked by irradiation with ionizing radiation. Accordingly, even when a resin has a melting point of about 260° C. before cross-linking, the resin can be used as a resin having an excellent reflow-resistance property by performing a cross-linking treatment. In general, a fluororesin having a low melting point has good processability. Therefore, preferably, a fluororesin having a carbon-hydrogen bond and having a low melting point is processed and is then cross-linked by irradiation with ionizing radiation. In this case, it is possible to impart good processability and heat resistance against a reflow temperature during mounting of an electronic device. Claim 3 corresponds to this preferred embodiment.

An example of the fluororesin that has a carbon-hydrogen bond and that is cross-linked by irradiation with ionizing radiation is ETFE having a melting point of 260° C. Examples of the fluororesin having a carbon-hydrogen bond further include polyvinylidene fluoride, polyvinyl fluoride, and tetrafluoroethylene-hexafluoropropylene copolymers. In the case of a copolymer such as an ethylene-tetrafluoroethylene copolymer, one or more other monomers may be copolymerized as long as the object of the present invention is not impaired. For example, when the copolymerization is conducted with maleic anhydride or the like, an improvement in the adhesiveness can be expected.

The fluororesin used in the present invention may have a reactive functional group at an end of the main chain and/or an end of a side chain thereof. Examples of the reactive functional group include a carbonyl group, groups having a carbonyl group, e.g., a carbonyl dioxy group and a haloformyl group, a hydroxyl group, and an epoxy group.

An invention of Claim 4 is the white reflective flexible printed circuit board according to any one of Claims 1 to 3, in which the inorganic white pigment contains at least one selected from the group consisting of titanium dioxide, barium sulfate, aluminum oxide, calcium carbonate, zinc oxide, and silicon oxide.

Pigments that are uniformly dispersed in the fluororesin so as to make the color of the resulting resin composition white are used as the inorganic white pigment. Among these pigments, by using a pigment containing at least one of titanium dioxide, barium sulfate, aluminum oxide, calcium carbonate, zinc oxide, and silicon oxide, a white reflective material layer having high whiteness and high reflectivity can be obtained. In order to obtain a good white reflective material layer, the inorganic white pigment is preferably blended in an amount of 10 parts by weight or more and 50 parts by weight or less relative to 100 parts by weight of the fluororesin.

The white reflective material layer included in the white reflective flexible printed circuit board of the present invention is composed of a resin composition containing a fluororesin and an inorganic white pigment. This resin composition is prepared by uniformly dispersing the inorganic white pigment in the fluororesin. The white reflective material layer can be produced by forming this resin composition into a film.

An invention of Claim 5 is the white reflective flexible printed circuit board according to any one of Claims 1 to 4, in which the resin composition contains a multifunctional monomer having a molecular weight of 1,000 or less and having at least two carbon-carbon double bonds in the molecule thereof in an amount of 0.5 parts by weight or more and 40 parts by weight or less relative to 100 parts by weight of the fluororesin.

By incorporating a multifunctional monomer having a molecular weight of 1,000 or less and having at least two carbon-carbon double bonds in the molecule thereof in the resin composition in an amount of 0.5 parts by weight or more and 40 parts by weight or less relative to 100 parts by weight of the fluororesin, the fluidity of the resin composition is increased to improve processability. In addition, the incorporation of the multifunctional monomer increases the effect of cross-linking. When the content of the multifunctional monomer is less than 0.5 parts by weight relative to 100 parts by weight of the fluororesin, the above effects are hardly obtained. On the other hand, a content of the multifunctional monomer exceeding 40 parts by weight is not preferable because kneading becomes difficult, and a problem such as bleed out may occur, and the possibility of color change increases.

Examples of the multifunctional monomer having a molecular weight of 1,000 or less and having at least two carbon-carbon double bonds in the molecule thereof include tris(acryloxyethyl) isocyanurate, tris(methacryloxyethyl) isocyanurate, and trimethylolpropane tri(meth)acrylate. These multifunctional monomers may be used alone or in combination of two or more monomers.

An invention of Claim 6 is the white reflective flexible printed circuit board according to any one of Claims 1 to 5, in which the white reflective material layer is bonded to a surface of the flexible printed circuit board with an adhesive.

In this invention, since the white reflective material layer is bonded to a surface of a flexible printed circuit board (which also includes a surface of a coverlay) with an adhesive, the white reflective flexible printed circuit board can be produced without significantly changing a process of producing a flexible printed circuit board. Specifically, in the production of a white reflective material layer in the related art, special members such as a photomask and a screen, and steps of exposure, development, and printing are necessary, and thus the production process needs to be changed. In contrast, in the structure of the present invention, the white reflective material layer can be integrated with a coverlay film by previously bonding the white reflective material layer to the coverlay film. Thus, a significant change in production process is not necessary. An epoxy adhesive, an acrylic adhesive, or the like may be used as the adhesive.

An invention of Claim 7 is the white reflective flexible printed circuit board according to Claim 6, in which an interface between the white reflective material layer and the adhesive is modified by a plasma treatment. By modifying the interface between the white reflective material layer and the adhesive by a plasma treatment, surface wettability of the fluororesin constituting the white reflective material layer can be improved to further improve the adhesive strength of the white reflective material layer. Herein, the term “plasma treatment” refers to a method in which a high-frequency electric field is applied to oxygen, nitrogen, air, or the like to generate a plasma state and a surface of the white reflective material is irradiated or bombarded with ions, radicals, or electrons in the plasma.

An invention of Claim 8 is lighting equipment including the white reflective flexible printed circuit board according to any one of Claims 1 to 7 and an LED mounted on the surface side constituted by the white reflective material layer of the white reflective flexible printed circuit board.

The lighting equipment produced by mounting a light-emitting element such as an LED on the white reflective flexible printed circuit board of the present invention described above can be used as an alternative light source of an incandescent light bulb, a halogen light bulb, or the like, a flat-panel display, a head lamp, or the like. The white reflective surface of the white reflective flexible printed circuit board of the present invention exhibits high whiteness and high reflectivity and has excellent light deterioration resistance and excellent thermal deterioration resistance. Accordingly, lighting equipment which has a high light intensity and in which color change does not occur for a long time can be produced by mounting an LED on the white reflective surface side of the white reflective flexible printed circuit board of the present invention. Furthermore, in the white reflective flexible printed circuit board included in the lighting equipment, since a repulsive force between the white reflective material layer and the flexible printed circuit board is small, the lighting equipment also has high durability. A resin having a coefficient of thermal expansion close to that of a polyimide and copper foil is preferably used as the fluororesin because a repulsive force generated by an increase in the temperature during use is also small, and thus the resulting lighting equipment has higher durability.

A white reflecting plate produced by forming, on a substrate, a white reflective material layer composed of a resin composition containing a fluororesin and an inorganic white pigment exhibits high whiteness and high reflectivity and has excellent light deterioration resistance and excellent thermal deterioration resistance. Thus, the white reflecting plate can be suitably used in applications other than the white reflective flexible printed circuit board of the present invention.

### Advantageous Effects of Invention

According to the white reflective flexible printed circuit board of the present invention, even when the white reflective material layer (white surface), which functions as a reflective surface of the flexible printed circuit board, is irradiated with light such as short-wavelength light for a long time, and even when the white reflective material layer is placed in a high-temperature environment for a long time, a decrease in the whiteness and reflectivity of the white reflective material layer is small and the white reflective material layer has excellent light deterioration resistance and excellent thermal deterioration resistance. Furthermore, the white reflective flexible printed circuit board of the present invention is excellent in terms of flexibility. Thus, even when the white reflective flexible printed circuit board functioning as a reflective surface is bonded to lighting equipment and the shape of the flexible printed circuit board is changed so as to conform to a curved shape or a step-like shape, the generation of a repulsive force is suppressed and a problem caused by the generation of the repulsive force is also suppressed. Accordingly, the white reflective flexible printed circuit board of the present invention is suitably used in, for example, lighting equipment for which high reflectivity is required, the lighting equipment having an LED mounted thereon.

### BRIEF DESCRIPTION OF DRAWINGS

FIG. 1 is a cross-sectional view of a white reflective flexible printed circuit board prepared in Embodiment 1.

FIG. 2 is a cross-sectional view of a white reflective flexible printed circuit board prepared in Embodiment 2.

### DESCRIPTION OF EMBODIMENTS

Next, embodiments for carrying out the present invention will be specifically described. It is to be understood that the present invention is not limited to these embodiments and can be changed to other embodiments as long as the object of the present invention is not impaired.

### Embodiment 1

A resin composition prepared by mixing 30 parts by weight of titanium dioxide (TiO₂) relative to 100 parts by weight of an ethylene-tetrafluoroethylene copolymer (ETFE) is formed into a film. Thus, a film having a thickness of 0.05 mm is prepared. The prepared film is irradiated with 400 kGy of accelerated electrons at an accelerating voltage of 2,000 kV. Furthermore, a plasma is generated by applying a high-frequency electric field to parallel plate electrodes using a high-frequency power supply of 13.56 MHz in an oxygen atmosphere, whose pressure is reduced to 100 Pa in a vacuum chamber, and a surface of the film is irradiated with the plasma for 30 minutes. Thus, a plasma-treated white reflective material layer is prepared.

A flexible printed circuit board is prepared in which a coverlay composed of a polyimide film is provided on a circuit of a copper clad laminate (CCL) with an adhesive layer therebetween (such that the circuit composed of copper is exposed), the CCL including a polyimide substrate and the circuit composed of copper and provided on the substrate. The white reflective material layer prepared above is bonded to a surface of the coverlay by heat pressing with an epoxy resin bonding sheet having a thickness of 0.025 mm therebetween. Thus, a white reflective flexible printed circuit board sample is prepared.

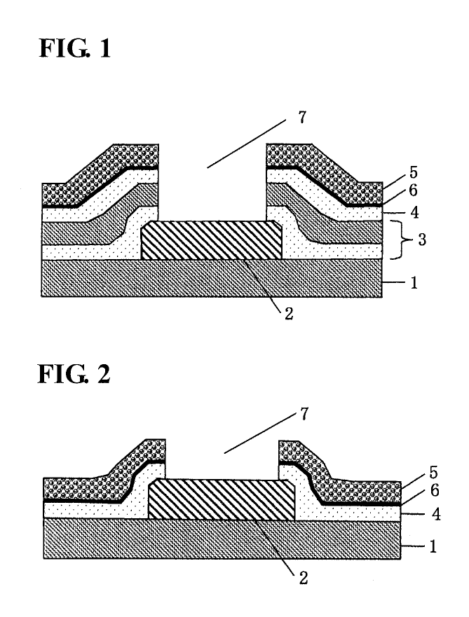

FIG. 1 is a cross-sectional view of the white reflective flexible printed circuit board prepared as described above. In the figure, reference numeral 1 denotes the polyimide substrate of the CCL, reference numeral 2 denotes the circuit composed of copper, and reference numeral 3 denotes the coverlay. This coverlay includes an adhesive layer (the lower layer in the figure) and the polyimide film (the upper layer in the figure). In the figure, reference numeral 4 denotes an adhesive layer that bonds the white reflective material layer, and reference numeral 5 denotes the white reflective material layer. A surface that contacts the adhesive layer 4 has been subjected to the plasma treatment and forms a plasma-treated surface 6. Reference numeral 7 in the figure denotes a portion on which an LED is to be mounted, and the circuit 2 composed of copper is exposed to the portion. An LED is to be mounted on this portion.

Even after the prepared sample is treated under a reflow condition in which LED mounting is assumed (at a maximum temperature of 260° C. for 30 seconds), and is then stored in a high-temperature chamber at 85° C. for 40,000 hours, the whiteness hardly changes, and the whiteness measured with a colorimeter (manufactured by Konica Minolta Holdings, Inc., Model: CR-13) is maintained at 90 or more. That is, the sample has an excellent thermal deterioration resistance. In addition, even when the sample is continued to be irradiated with white LED light, no significant change in whiteness is observed, and the whiteness measured with a colorimeter (manufactured by Konica Minolta Holdings, Inc., Model: CR-13) is maintained at 90 or more. Furthermore, a decrease in the reflectivity compared with the initial reflectivity is also small. That is, the sample has an excellent light deterioration resistance.

### Embodiment 2

A resin composition prepared by mixing 30 parts by weight of titanium dioxide (TiO₂) relative to 100 parts by weight of an ethylene-tetrafluoroethylene copolymer (ETFE) is formed into a film. Thus, a film having a thickness of 0.05 mm is prepared. The prepared film is irradiated with 600 kGy of accelerated electrons at an accelerating voltage of 2,000 kV. Furthermore, a plasma is generated by applying a high-frequency electric field to a roller electrode using a high-frequency power supply of 13.56 MHz in a nitrogen atmosphere, whose pressure is reduced to 50 Pa in a vacuum chamber, and a surface of the film is irradiated with the plasma at a rate of 5 min/m. Thus, a plasma-treated white reflective material layer is prepared.

A CCL in which a circuit composed of copper is provided on a polyimide substrate is prepared. The white reflective material layer prepared above is bonded onto the circuit by heat pressing with an epoxy resin bonding sheet having a thickness of 0.025 mm therebetween such that the circuit composed of copper is exposed. Thus, a white reflective flexible printed circuit board sample is prepared.

FIG. 2 is a cross-sectional view of the white reflective flexible printed circuit board prepared as described above. In the figure, reference numeral 1 denotes the polyimide substrate of the CCL, reference numeral 2 denotes the circuit composed of copper, reference numeral 4 denotes an adhesive layer that bonds the white reflective material layer, and reference numeral 5 denotes the white reflective material layer. A surface that contacts the adhesive layer 4 has been subjected to the plasma treatment and forms a plasma-treated surface 6. Reference numeral 7 in the figure denotes a portion on which an LED is to be mounted, and the circuit 2 composed of copper is exposed to the portion. An LED is to be mounted on this portion.

Even after the prepared sample is treated under a reflow condition in which LED mounting is assumed (at a maximum temperature of 260° C. for 30 seconds), and is then stored in a high-temperature chamber at 85° C. for 40,000 hours, the whiteness hardly changes, and the whiteness measured with a colorimeter (manufactured by Konica Minolta Holdings, Inc., Model: CR-13) is maintained at 90 or more. That is, the sample has an excellent thermal deterioration resistance. In addition, even when the sample is continued to be irradiated with white LED light, no significant change in whiteness is observed, and the whiteness measured with a colorimeter (manufactured by Konica Minolta Holdings, Inc., Model: CR-13) is maintained at 90 or more. Furthermore, a decrease in the reflectivity compared with the initial reflectivity is also small. That is, the sample has an excellent light deterioration resistance.

### (Repulsive Force Due to Change in Shape of White Reflective Material Layer)

The Young's modulus of PTFE is 0.5 GPa. Thus, the Young's modulus of a fluororesin is usually 1 GPa or less. In contrast, the Young's modulus of an epoxy resin is 2 GPa or more. The relationship among the Young's modulus, a stress (corresponding to a repulsive force generated during a change in shape), and a strain (corresponding to the amount of change in shape) is represented by “Stress=Young's modulus×Strain”. Accordingly, a repulsive force generated when the shape of a white reflective flexible printed circuit board having a white reflective material layer is changed so as to conform to a curved shape or a step-like shape of a reflective surface of lighting equipment is smaller in the present invention, in which the white reflective material layer is composed of a fluororesin, than in the related art, in which the white reflective material layer is composed of another resin such as an epoxy resin.

### REFERENCE SIGNS LIST

1 polyimide substrate
2 circuit composed of copper
3 coverlay
4 adhesive layer
5 white reflective material layer
6 plasma-treated surface
7 portion on which LED is to be mounted

1. A white reflective flexible printed circuit board comprising a flexible printed circuit board and a surface constituted by a white reflective material layer, wherein the white reflective material layer is composed of a resin composition containing a fluororesin and an inorganic white pigment.

2. The white reflective flexible printed circuit board according to claim 1, wherein the fluororesin is selected from the group consisting of an ethylene-tetrafluoroethylene copolymer, a tetrafluoroethylene-hexafluoropropylene copolymer, a tetrafluoroethylene-perfluoro alkyl vinyl ether copolymer, and polytetrafluoroethylene.

3. The white reflective flexible printed circuit board according to claim 1, wherein the fluororesin has a carbon-hydrogen bond and is cross-linked by irradiation with ionizing radiation.

4. The white reflective flexible printed circuit board according to claim 1, wherein the inorganic white pigment contains at least one selected from the group consisting of titanium dioxide, barium sulfate, aluminum oxide, calcium carbonate, zinc oxide, and silicon oxide.

5. The white reflective flexible printed circuit board according to claim 1, wherein the resin composition contains a multifunctional monomer having a molecular weight of 1,000 or less and having at least two carbon-carbon double bonds in the molecule thereof in an amount of 0.5 parts by weight or more and 40 parts by weight or less relative to 100 parts by weight of the fluororesin.

6. The white reflective flexible printed circuit board according to claim 1, wherein the white reflective material layer is bonded to a surface of the flexible printed circuit board with an adhesive.

7. The white reflective flexible printed circuit board according to claim 6, wherein an interface between the white reflective material layer and the adhesive is modified by a plasma treatment.

8. Lighting equipment comprising the white reflective flexible printed circuit board according to claim 1 and an LED mounted on the surface side constituted by the white reflective material layer of the white reflective flexible printed circuit board.
